(19) United States
(12) Patent Application Publication
(10) Pub. No.: US 2005/0268183 A1
(43) Pub. Date: Dec. 1, 2005

(54) Local area network measurement test device

(76) Inventor: Mark G. Barmettler, Cedar Hill, TX (US)

Correspondence Address: CONLEY ROSE, P.C., 5700 GRANITE PARKWAY, SUITE 330, PLANO, TX, 75024, US

(21) Appl. No.: 10/853,487

(22) Filed: May 25, 2004

(51) Int. Cl. G01R 31/28; G01R 27/04; G01R 27/32

(52) U.S. Cl. 714/712

(57) ABSTRACT

A device for certifying a local area network is provided. The device includes a measurement component to generate test signals for transmission over the local area network. The measurement component is operable to receive and measure test signals transmitted over the local area network. The device includes a network adapter having a first portion coupleable to communicate with the local area network and a second portion operable to communicate with the measurement component. The network adapter communicates signals received from the local area network to the measurement component. The device also includes a portable computing device, such as a personal digital assistant, communicatively coupleable to the measurement component to analyze signals received from the measurement device to certify the local area network. The signals sent from the measurement component are based on measurements taken by the measurement component of test signals received from the local area network.

### CROSS-REFERENCE TO RELATED APPLICATIONS

None.

### STATEMENT REGARDING FEDERALLY SPONSORED RESEARCH OR DEVELOPMENT

Not applicable.

### REFERENCE TO A MICROFICHE APPENDIX

Not applicable.

### FIELD OF THE INVENTION

This invention relates in general to the field of measurement devices for testing information system cabling and connectors and more specifically, but not by way of limitation, to a system and method for separating the functions of network testing devices into discrete components.

### BACKGROUND OF THE INVENTION

Information system networks, such as local area networks or LANs, might include cabling, connectors, and adapters for communicating data signals. The cabling, connectors, and adapters installed in an office or other structure must meet certain standards to assure that the network is operable for the use of businesses in the structure. To certify network cabling, a measurement or test device may be connected to the network of the structure. The device generates precise test signals that are transmitted across the network. The characteristics of the test signal are accurately measured and analyzed to evaluate the integrity of the cabling.

In some scenarios, a network testing device injects a test signal into a network, the signal travels through the network, and another testing device receives and analyzes the signal. In other scenarios, a network testing device injects a test signal into a network and the signal travels through the network and returns to the same testing device, which then receives and analyzes the signal. In either case, the testing device that receives the test signal performs the measurements on the signal, analyzes the data obtained in the measurements, and display the results.

The network testing devices are generally provided with components and circuitry, such as processor(s) and programming, operable for such functions. The testing device may include displays, such as an LED or LCD displays, for displaying, for example, alpha-numeric and other characters and graphical illustrations. Existing network testing devices are provided such that all components for performing the measurement, analysis, and display functions are contained within a single body or unit comprising the network testing device. The term local area network or network, as used herein, may include, but should not be limited to, networks provided with standard copper cabling, those using fiber optic cabling, as well as wireless and other networks.

Connecting the test devices to networks is typically accomplished using a network adapter. The adapter may connect to a jack that connects to the cabling comprising the network. The adapters may be channel adapters, which contain a female receiving portion or jack, or link adapters, which are male plugs presented from the network. The term network adapter, as used herein, includes link and channel adapters as well as other types of network adapters such as, but not limited to, multi-mode and single mode optical network adapters. The correct channel adapter or link adapter, depending upon the topology at a particular location in the network, is required to connect a particular device to the network.

A set of components and connections traditionally used in the testing of a network is shown in FIG. 1. An adapter 120 connects to a network 110 via connection 115. As discussed above, the adapter 120 may be a channel adapter, link adapter, multi-mode or single mode adapter, for example. The adapter 120 allows a network testing device 130 to be connected to the network 110. The network testing device 130 connects to the adapter 120 via connection 125. Connection 125 may be a direct connection such as a plug and a socket or it may be a cable that allows the network testing device 130 to be removed some distance from the adapter 120. A test signal can flow from the network 110, through the connection 115, through the adapter 120, through the connector 125, to the network testing device 130, where it can be measured and analyzed.

### SUMMARY OF THE INVENTION

The present disclosure provides a device for certifying a local area network. The device includes a measurement component to generate test signals for transmission over the local area network. The measurement component is operable to receive and measure test signals transmitted over the local area network. The device includes a network adapter having a first portion coupleable to communicate with the local area network and a second portion operable to communicate with the measurement component. The network adapter communicates signals received from the local area network to the measurement component. The device also includes a portable computing device communicatively coupleable to the measurement component to analyze signals received from the measurement device to certify the local area network. The signals sent from the measurement component are based on measurements taken by the measurement component of test signals received from the local area network.

In one embodiment, a network test device for testing a network is provided. The network test device includes an adapter operable to communicate with the network. The network test device includes a measurement system in communication with the adapter and operable to generate test signals for transmission over the network. The measurement component further operable to measure test signals received from the network. The network test device includes a portable computing device operable to receive communications from the measurement system. The portable computing device is operable to display, and in some embodiments analyze, information regarding the signals received from the measurement device to certify the local area network. A data transfer component is provided to promote communication between portable computing device and the measurement system.

In another embodiment, the present disclosure provides a method of testing a local area network. The method includes communicatively coupling a measurement component to a portable computing device. The measurement component is operable to generate test signals for testing the local area network. The method includes coupling an adapter to the local area network and generating test signals by the measurement component. The method also provides for communicating test signals generated by the measurement device to the local area network via the adapter.

These and other features and advantages will be more clearly understood from the following detailed description taken in conjunction with the accompanying drawings and claims.

### BRIEF DESCRIPTION OF THE DRAWINGS

FIG. 1 illustrates components and connections in prior art network test devices.

FIG. 2 is a generalized block diagram illustrating components and connections in a network tester according to one embodiments of the present disclosure.

FIG. 3a illustrates components and connections of the network tester according to another embodiment of the present disclosure.

FIG. 3b illustrates additional component detail and connectivity for the network tester illustrated in FIG. 3a.

FIG. 4 illustrates components and connections of the network tester according to still another embodiment of the present disclosure.

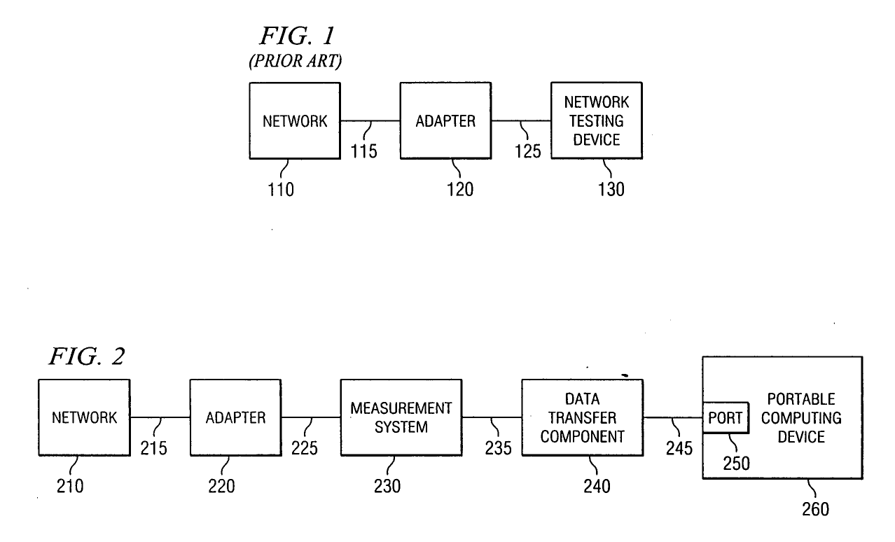

For a more complete understanding of the presentation and the advantages thereof, reference is now made to the following brief description, taken in connection with the accompanying drawings and detailed description, wherein like reference numerals represent like parts.

### DETAILED DESCRIPTION OF THE PREFERRED EMBODIMENTS

It should be understood at the outset that although an exemplary implementation of one or more embodiments of the present invention are illustrated below, the present system may be implemented using any number of techniques, whether currently known or in existence. The present disclosure should in no way be limited to the exemplary implementations, drawings, and techniques illustrated below, including the exemplary design and implementation illustrated and described herein, but may be modified within the scope of the appended claims along with their full scope of equivalents.

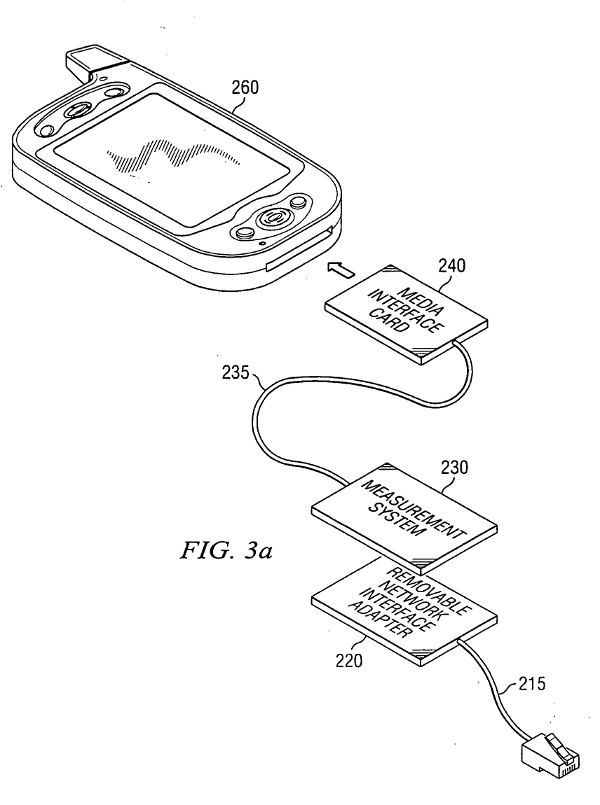

A set of components and connections that might be used in various embodiments of the present invention are shown in FIG. 2. As in the prior art, an adapter 220 connects to a network 210 via connection 215. The adapter 220 allows devices to be connected to the network 210 via connection 225. Connection 225 may be a direct connection such as a plug and a socket or it may be a cable that allows the devices to be removed some distance from the adapter 220.

In various embodiments, a component that can be referred to as a measurement system 230 connects to the adapter 220 via connection 225. The measurement system 230 receives a test signal from the adapter 220 and, via connection 235, passes data extracted from the test signal to a component that can be referred to as a data transfer component 240. Connection 235 may be a direct connection such as a plug and a socket or it may be a cable that allows the measurement system 230 and the data transfer component 240 to be removed some distance from each other. The measurement system 230 includes components and circuitry to, for example, precisely generate one or more signals, and transmit and receive, such as in storage components, these signal for analysis, which is well known in the art. It will be appreciated that to accurately test networks requires the components and circuitry of the measurement system 23 may be required to be highly accurate.

The data transfer component 240 transfers the data, via connection 245, to a portable computing device 260. The data transfer can be accomplished by several different means, as described below. The portable computing device 260 might be a personal digital assistant (PDA), a laptop computer, a palm top, tablet personal computer, or some other portable device for processing and displaying data. Although various operating systems may be used, when a PDA is employed as the portable computing device 260, WinCE may be the preferred operating system. A port 250 might be present within the portable computing device 260 by means of which data can be transferred into the portable computing device 260.

The measurement system 230, the data transfer component 240, and/or the portable computing device 260 analyze the test signal to accomplish the network testing. Analysis of the test signal may include as converting the test signal into digital data, processing the digital data as necessary for evaluation of the integrity of a network, and displaying the processed data on a display. In various embodiments, analysis of the test signal can be performed individually by either the measurement system 230, the data transfer component 240, or the portable computing device 260. Alternatively, the analysis functions can be divided among various combinations of the measurement system 230, the data transfer component 240, and the portable computing device 260.

For example, in one embodiment, the measurement system 230 obtains the test signal from the adapter 220 and converts the test signal into digital data. The measurement system 230 passes the digital data to the data transfer component 240, which then transfers the digital data to the portable computing device 260. Software in the portable computing device 260 processes the data as necessary to complete the network testing and then displays the processed data. In other embodiments, the data transfer component 240 may perform some processing of the data before the data is transferred to the portable computing device 260.

In the cases where the data transfer component 240 merely transfers data but performs no processing on the data, the data transfer component 240 might be a standard memory card of the types that are commercially available under names such as Compact Flash Card, Secure Digital Card, Multimedia Card, and the like. Memory cards, flash card, or cards of these types, as used herein, may refer to the devices well known under these names, but also may refer to the standard interfaces used by these devices whether with similar, different or additional circuitry, components and functionality. A user might insert the memory card into a standard port in the measurement system 230, which could then write digital data onto the memory card. The memory card could then be removed from the measurement system 230 and inserted into a standard port 250 in the portable computing device 260, which could then read the digital data from the memory card.

If the data transfer component 240 performs processing of data, the data transfer component 240 might contain both data processing elements and digital data storage elements. In one embodiment, the data transfer component 240 has a single, standard connector similar to those found on standard memory cards. The standard connector can be inserted into standard ports in the measurement system 230 and in the portable computing device 260. A data transfer component 240 such as this can be used to transfer data from the measurement system 230 to the portable computing device 260 in the manner described above. The data transfer component 240 can perform processing of the data while connected to either the measurement system 230 or the portable computing device 260. The portable computing device 260 could then read the data from the data transfer component 240 and perform further processing.

In another embodiment, a cable or other connection mechanism 235 is attached to the data transfer component 240 in addition to the standard connector similar to those found on standard memory cards. The cable or other connection mechanism 235 can connect the data transfer component 240 to the measurement system 230 and the standard connector can connect the data transfer component 240 to the portable computing device 260. When the measurement system 230, the data transfer component 240, and the portable computing device 260 are connected in this manner, data can flow in an uninterrupted stream from the measurement system 230, through the data transfer component 240, to the portable computing device 260.

In any of the above cases, connection 245 may be the physical insertion of a standard connector similar to those found on memory cards into the port 250 of the portable computing device 260.

In another embodiment, the data transfer component 240 is a wireless data transmitter. The data transfer component 240 connects to and receives data from the measurement system 230 in any of the manners described above and then transmits the data wirelessly to the portable computing device 260. In this case, connection 245 is the wireless transmission of data from the data transfer component 240 to the port 250 of the portable computing device 260. Processing of data would typically not be performed in the data transfer component 240 in this embodiment but would instead be done by the measurement system 230 and/or the portable computing device 260. Wireless data transfer protocols such as Bluetooth, wireless Ethernet, or infrared light could be used. In some embodiments, GPS (global positioning system) may be provided to readily and accurately provide location and positioning information.

FIG. 2 illustrates the general form that the components can take in various embodiments. In some embodiments, the measurement system 230 and the data transfer component 240 are physically separate components as shown. The connection 235 between them can be a cable, a direct connection such as a plug and a socket, or some other connection. The data transfer component 240, as described above, can be a standard memory card, a component with a connector similar to those found on standard memory cards, or a wireless transmission device.

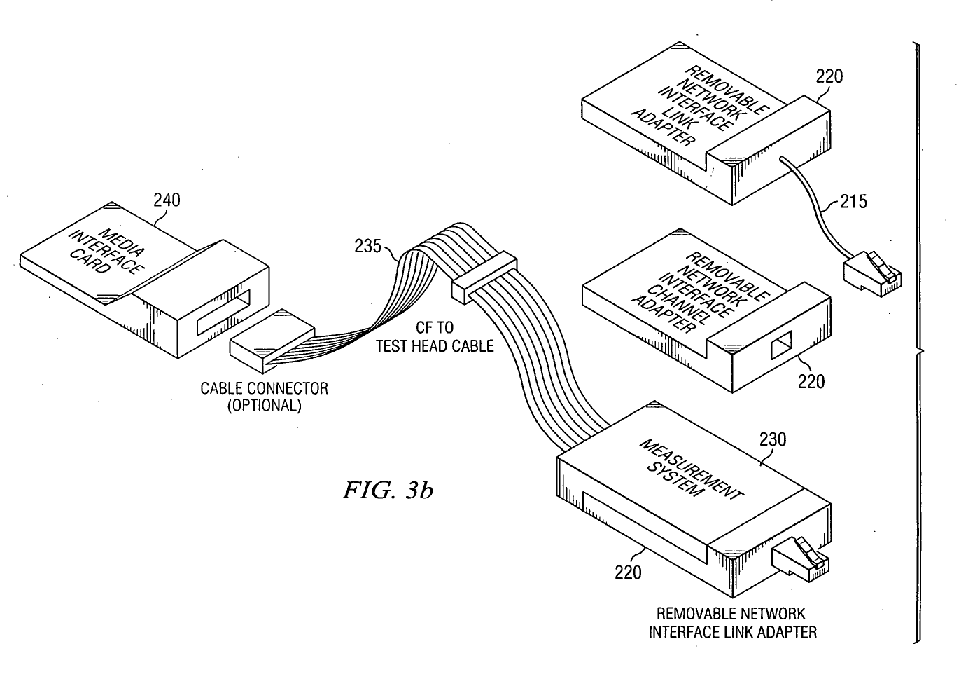

FIGS. 3a and 3b show a set of components that could be used in several of the embodiments where the measurement system 230 and the data transfer component 240 are separate components. Various adapters 220 can be coupled to a measurement system 230. The adapters 220 can connect directly to a network or can connect to a network through a cable 215. In FIG. 3, an adapter 220 is directly coupled to the measurement system 230 and the connection (225 in FIG. 2) between them is not visible. FIG. 3b illustrates an exemplary configuration by which the combination shown in FIG. 3a may be constructed and connected.

The measurement system 230 connects to a data transfer component 240 via a cable 235. The data transfer component 240 is a media interface card to which the cable 235 can be attached for connection to the measurement system 230. The data transfer component 240 also has a standard connector (not shown) by which it can be connected to a portable computing device 260. In FIG. 3a, the portable computing device 260 is a PDA.

In other embodiments, the measurement system 230 and the data transfer component 240 are combined into a single unit. In this case, connection 235 would not be present. This single unit performs the functions of obtaining the test signal from the adapter 220 and transferring data to the portable computing device 260. Analysis of the data could be performed by the single unit, the portable computing device 260, or both. The single unit might have a cable 225 for connection to an adapter 220. Alternatively, an adapter 220 could be built in to the single unit. The single unit might have a connector such as those found on standard memory cards so that the single unit can be inserted into the standard port 250 on the portable computing device 260. Alternatively, the single unit might contain a wireless data transmission system for sending data to the portable computing device 260.

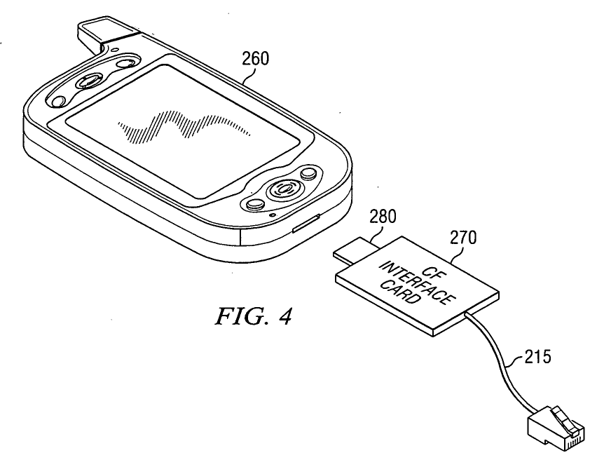

FIG. 4 shows a set of components that could be used in several of the embodiments where the measurement system and the data transfer component are combined into a single unit 270. In this case, an adapter is coupled, such as in a removable manner, to the single unit 270. A standard connector 280 allows the single unit 270 to be connected to a portable computing device 260, in this case a PDA. A cable 215 allows the single unit 270 to be connected to a network.

In some embodiments, the various components of the present disclosure, such as the measurement system 230, the adapter 220, the data transfer component 240, and the portable computing device 260, may communicatively coupleable to one another which may include a physical connection or coupling, or non-physical connection, such as wireless communication, to promote communication between the various components.

In various embodiments, the portable computing device 260 might simply display the data that has been processed by the measurement system 230 and/or by the data transfer component 240. In one embodiment, the present system includes software operably loaded on the portable computing device 260 for analyzing and processing the network signals received by the measurement system 230. Such software and programming may be similar to that currently embedded on integrated unitary network test devices and certain adaptations would be necessary to enable the software on the portable computing device 260, which could be accomplished by one skilled in the art.

In several of the embodiments, the portable computing device 260 may contain this analysis and processing software and/or hardware that is capable of processing the data has been collected by the measurement system 230 and transferred by the data transfer component 240. In this manner, thus, the present disclosure provides a network test device that is significantly less expensive, since many individuals and organization currently own PDA, such as the portable computing device 260. Only the measurement system 230 and adapter(s) 220 would need to be purchased and then the analysis and processing software would be loaded on the portable computing device 260 to begin network testing. Thus, the present system leverages the architecture and processing capabilities of the portable computing device 260.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein, but may be modified within the scope of the appended claims along with their full scope of equivalents. For example, the various elements or components may be combined or integrated in another system or certain features may be omitted, or not implemented.

Also, techniques, systems, subsystems and methods described and illustrated in the various embodiments as discrete or separate may be combined or integrated with other systems, modules, techniques, or methods without departing from the scope of the present disclosure. Other items shown as directly coupled or communicating with each other may be coupled through some interface or device, such that the items may no longer be considered directly coupled to each but may still be indirectly coupled and in communication with one another. Other examples of changes, substitutions, and alterations are ascertainable by on skilled in the art and could be made without departing from the spirit and scope disclosed herein.

1. A device for analyzing a local area network, comprising:
a measurement component operable to generate test signals for transmission over the local area network, the measurement component further operable to receive and measure test signals transmitted over the local area network;
a network adapter having a first portion coupleable to communicate with the local area network and a second portion operable to communicate with the measurement component, the network adapter operable to communicate signals received from the local area network to the measurement component; and
a portable computing device communicatively coupleable to the measurement component to display information related to the signals received from the measurement device, the signals based on measurements by the measurement component of test signals received from the local area network.

2. The device of claim 1, wherein the portable computing device further includes a processor programmed to analyze the signals received from the measurement device to certify the network.

3. The device of claim 1, wherein the portable computing device further includes a storage device and a processor and further wherein analysis software is loaded on the storage device of the portable computing device, the analysis software operable, via the processor of the portable computing device, for analysis of the signals received from the measurement component to certify the local area network.

4. The device of claim 1, wherein the communication between the portable computing device and the measurement component is further defined as radio frequency communication.

5. The device of claim 1, wherein the communication between the portable computing device and the measurement component is further defined as optical communication.

6. The device of claim 1, wherein the portable computing device is further defined as a personal digital assistant.

7. The device of claim 1, wherein the portable computing device is further defined as a laptop computer.

8. The device of claim 1, wherein the network adapter is further defined as a channel adapter.

9. The device of claim 1, wherein the network adapter is further defined as a link adapter.

10. The device of claim 1, wherein the communication between the portable computing device and the measurement component is further defined as a cabled communication.

11. The device of claim 1, wherein the information related to the signals displayed by the portable computing device is further defined as at least a portion of the signal.

12. The device of claim 1, wherein the information related to the signals displayed by the portable computing device is further defined as including measurement information of at least a portion of the signal.

13. The device of claim 1, wherein at least a portion of the display information related to the signals received from the measurement device is used to certify the local area network.

14. A network test device for testing a network, the network test device comprising:
an adapter operable to communicate with the network;
a measurement system in communication with the adapter and operable to generate test signals for transmission over the network, the measurement component further operable to measure test signals received from the network;
a portable computing device operable to receive communications from the measurement system, the portable computing device operable to display information related to the signals received from the measurement device; and
a data transfer component to promote communication between portable computing device and the measurement system.

15. The network test device of claim 14, wherein the measurement system is operable on a media type card and the data transfer component is further defined as an interface on the media type card for coupling the media type card to a receiver portion on the portable computing device.

16. The network test device of claim 14, wherein the data transfer component is a flash memory card operable to store information related to the test signals, the flash memory card operable to communicate, via an interface, with the measurement system, the flash memory card operably readable, via a second interface on the portable computing device, by the computing device.

17. The network test device of claim 14, wherein the measurement system is removably coupleable and uncoupleable to the adapter.

18. The network test device of claim 14, wherein portable computing device includes a wireless communication portion operable to communicate with the data transfer component.

19. The network test device of claim 18, wherein the data transfer component is a wireless communication component operably coupled to the measurement system to communicate with the portable computing device.

20. The network test device of claim 19, wherein the wireless communication portion of the portable communication device and the wireless communication component of the measurement system communicate via RF signals.

21. A method of testing a local area network, comprising:
communicatively coupling a measurement component to a portable computing device, the measurement component operable to generate test signals for testing the local area network;
coupling an adapter to the local area network;
generating test signals by the measurement component; and
communicating test signals generated by the measurement device to the local area network via the adapter.

22. The method of claim 21, further comprising:
measuring test signals, by the measurement component, received from the local area network via the adapter;
signaling, by the measurement component, the portable computing device regarding measurement of the test signals; and
displaying, by the portable computing device, information related to the signals on a display of the portable computing device.

23. The method of claim 21, wherein measurement component includes measurement circuitry provided on a flash type card and wherein the portable computing device is a personal digital assistant.

24. The method of claim 21, wherein measurement component includes measurement circuitry provided on a media type card operable to connect to the portable computing device and wherein portable computing device receives the media type card via an interface of the portable computing device.

25. The method of claim 21, wherein the measurement component and the portable computing device both include a wireless communication component and wherein the measurement component and the portable computing device communicate wirelessly via the respective wireless communication components.

26. The method of claim 22, wherein the measurement component removably couples to communicate with one of a link adapter, a channel adapter, a multi-mode optical adapter, and a single mode optical adapter and wherein the measurement component communicates, via a cable, with a media card operable to removably couple with the portable computing device to promote communication between the measurement component and the portable computing device.
